(19) United States
(12) Patent Application Publication
(10) Pub. No.: US 2026/0090271 A1
(43) Pub. Date: Mar. 26, 2026

(54) HEAT DISSIPATION POWER GENERATION MODULE

(71) Applicant: COMPAL ELECTRONICS, INC., Taipei City (TW)

(72) Inventors: Cheng-Shiue Jan, Taipei City (TW); Chih-Wen Chiang, Taipei City (TW); Ching-Tai Chang, Taipei City (TW); Chien-Chu Chen, Taipei City (TW)

(73) Assignee: COMPAL ELECTRONICS, INC., Taipei City (TW)

(21) Appl. No.: 18/925,044

(22) Filed: Oct. 24, 2024

Related U.S. Application Data
(60) Provisional application No. 63/683,683, filed on Aug. 15, 2024.

(30) Foreign Application Priority Data
Sep. 26, 2024 (TW) 113136649

(51) Int. Cl. H10N 10/13; H05K 7/14; H05K 7/20

(52) U.S. Cl. CPC H10N 10/13; H05K 7/1492; H05K 7/20145; H05K 7/20336; H05K 7/2039; H05K 7/208

(57) ABSTRACT

A heat dissipation power generation module adapted for a server is provided. The heat dissipation power generation module includes a first heat dissipation component, a thermoelectric component and a second heat dissipation component. The first heat dissipation component is thermally coupled to at least one heat source of the server. The thermoelectric component is disposed on the first heat dissipation component. The thermoelectric component is located between the first heat dissipation component and the second heat dissipation component. The first heat dissipation component and the second heat dissipation component form a temperature difference at two opposite sides of the thermoelectric component, and the thermoelectric component generates an electrical energy through the temperature difference.

### CROSS-REFERENCE TO RELATED APPLICATION

This application claims the priority benefit of U.S. provisional application Ser. No. 63/683,683, filed on Aug. 15, 2024 and Taiwan application no. 113136649, filed on Sep. 26, 2024. The entirety of the above-mentioned patent application is hereby incorporated by reference herein and made a part of this specification.

### BACKGROUND

### Technical Field

The disclosure relates to a module, and particularly relates to a heat dissipation power generation module.

### Description of Related Art

The modern server includes the heat sources (such as the central processing unit and the graphic processing unit), and may use the heat dissipation module to dissipate heat from the heat sources. As the server performance improves, the thermal energy generated by the heat sources also increases. However, the modern heat dissipation module only uses to dissipate heat from the heat sources without effectively utilizing the thermal energy from the heat sources, resulting in energy waste.

### SUMMARY

The disclosure provides a heat dissipation power generation module that may simultaneously perform the heat dissipation and generate the electrical energy.

The heat dissipation power generation module of the disclosure is adapted for a server. The heat dissipation power generation module includes a first heat dissipation component, a thermoelectric component and a second heat dissipation component. The first heat dissipation component is thermally coupled to at least one heat source of the server. The thermoelectric component is disposed on the first heat dissipation component. The thermoelectric component is located between the first heat dissipation component and the second heat dissipation component. The first heat dissipation component and the second heat dissipation component form a temperature difference at two opposite sides of the thermoelectric component, and the thermoelectric component generates an electrical energy through the temperature difference.

Based on the above, the first heat dissipation component of the heat dissipation power generation module of the disclosure exchanges heat with the heat source of the server, forming a high temperature on one side of the thermoelectric component. The second heat dissipation component forms a low temperature on the other side of the thermoelectric component. The thermoelectric component generates the electrical energy through the temperature difference at the two sides. Thereby, the heat dissipation power generation module may dissipate heat from the heat source while simultaneously recycling the thermal energy dissipated by the heat source to generate the electrical energy, achieving the efficacy of energy recycling and heat dissipation.

### BRIEF DESCRIPTION OF THE DRAWINGS

FIG. 1 is a schematic diagram of a heat dissipation power generation module according to an embodiment of the disclosure.

FIG. 2 is a cross-sectional view of the heat dissipation power generation module in FIG. 1.

FIG. 3 is an exploded view of the heat dissipation power generation module in FIG. 2.

FIG. 4 is a cross-sectional view of a heat dissipation power generation module according to another embodiment of the disclosure.

FIG. 5 is a cross-sectional view of a heat dissipation power generation module according to another embodiment of the disclosure.

FIG. 6 is a cross-sectional view of a heat dissipation power generation module according to another embodiment of the disclosure.

FIG. 7 is a cross-sectional view of a heat dissipation power generation module according to another embodiment of the disclosure.

FIG. 8 is a cross-sectional view of a heat dissipation power generation module according to another embodiment of the disclosure.

FIG. 9 is an exploded view of the heat dissipation power generation module in FIG. 8.

### DESCRIPTION OF THE EMBODIMENTS

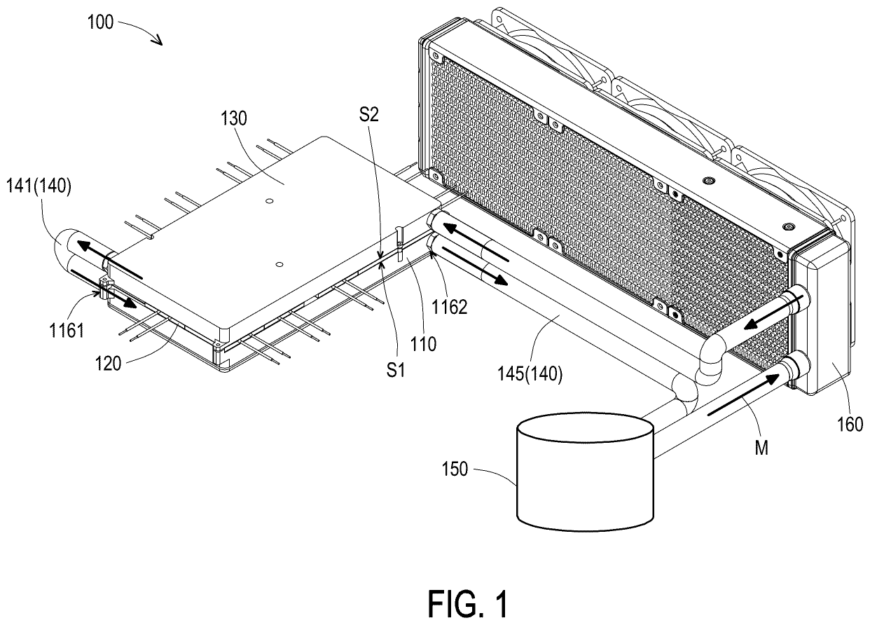

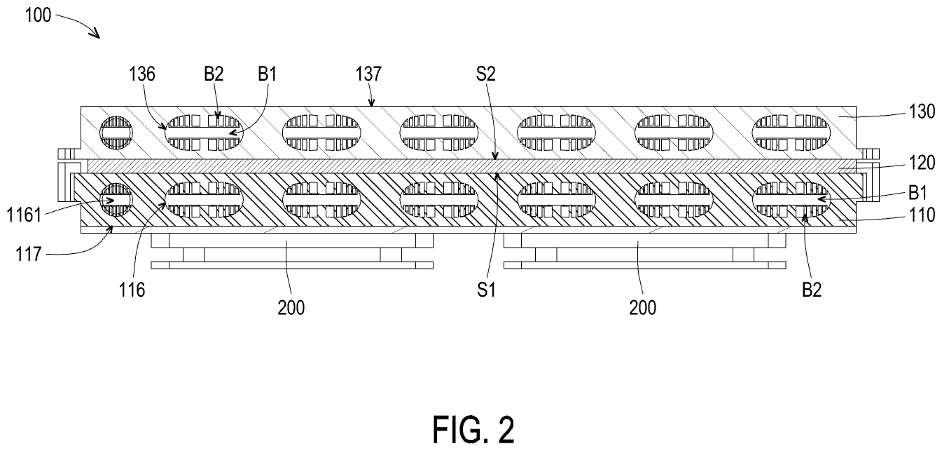

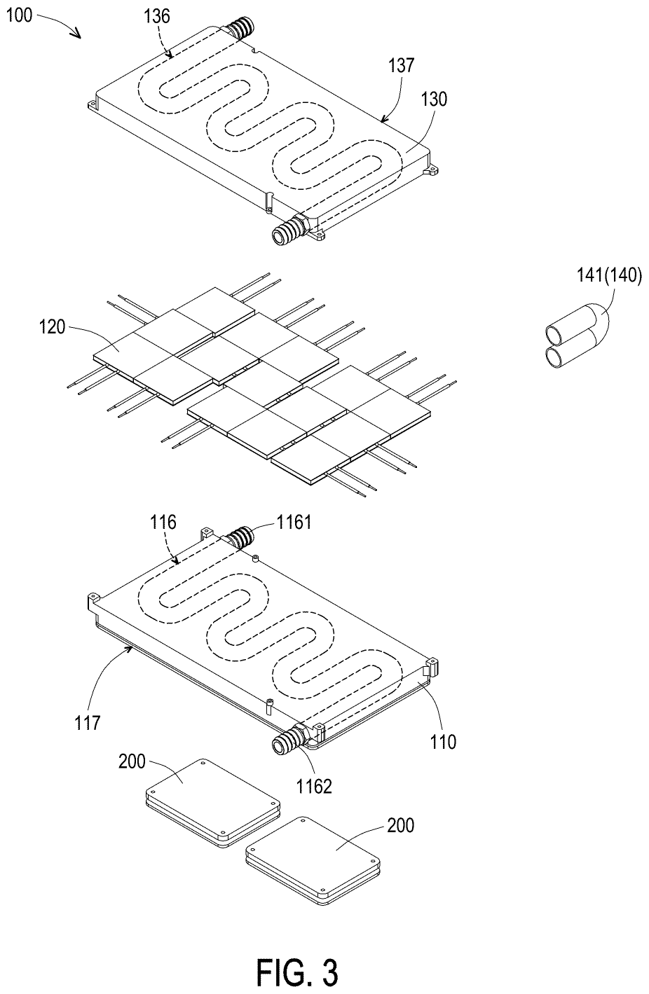

FIG. 1 is a schematic diagram of a heat dissipation power generation module according to an embodiment of the disclosure. FIG. 2 is a cross-sectional view of the heat dissipation power generation module in FIG. 1. FIG. 3 is an exploded view of the heat dissipation power generation module in FIG. 2. Please refer to FIG. 1 to FIG. 3 simultaneously, the heat dissipation power generation module 100 may be used in a server 10. The heat dissipation power generation module 100 includes a first heat dissipation component 110, a thermoelectric component 120, and a second heat dissipation component 130. The first heat dissipation component 110 is thermally coupled to at least one heat source 200 of the server 10. The thermoelectric component 120 is disposed on the first heat dissipation component 110. The thermoelectric component 120 is located between the first heat dissipation component 110 and the second heat dissipation component 130.

The heat dissipation power generation module 100 of this embodiment is a water-cooling heat dissipation power generation module, but not limited thereto. The first heat dissipation component 110 includes a first inner pipeline 116, the second heat dissipation component 130 includes a second inner pipeline 136, and the first inner pipeline 116 is communicated to the second inner pipeline 136. A heat dissipation medium M flows within the first inner pipeline 116 and the second inner pipeline 136. Specifically, the heat dissipation medium M with the low thermal energy flows within the second heat dissipation component 130 (the second inner pipeline 136), causing a side S2 of the thermoelectric component 120 connected to the second heat dissipation component 130 to have a low temperature. The heat dissipation medium M in the first heat dissipation component 110 exchanges the heat with the heat source 200 to dissipate heat from the heat source 200. After the heat exchange, the heat dissipation medium M with the high thermal energy flows within the first heat dissipation component 110 (the first inner pipeline 116), causing a side S1 of the thermoelectric component 120 connected to the first heat dissipation component 110 to have a high temperature. The first heat dissipation component 110 and the second heat dissipation component 130 form a temperature difference on the two opposite sides S1, S2 of the thermoelectric component 120 through the heat source 200 and the heat dissipation medium M, and the thermoelectric component 120 generates an electrical energy through the temperature difference.

Thereby, the heat dissipation power generation module 100 recycles the thermal energy dissipated by the heat source 200 while dissipating the heat from the heat source 200, to generate the electrical energy through the thermoelectric component 120, enabling the heat dissipation power generation module 100 to possess the efficacy of the energy recycling and the heat dissipation. The thermoelectric component 120 may be electrically connected to a circuit board of the server 10 to provide the electrical energy or electrically connected to an energy storage device to store the electrical energy.

As shown in FIG. 1 and FIG. 2, the heat dissipation power generation module 100 further includes a pipeline component 140, a pump 150, and a cooling component 160. The cooling component 160 may be a water cooling radiator, but not limited thereto. The pipeline component 140 includes a communicating pipeline 141 and a plurality of connecting pipelines 145. The communicating pipeline 141 of the pipeline component 140 connects the first inner pipeline 116 and the second inner pipeline 136. The pump 150 is communicated to the cooling component 160 and the first inner pipeline 116 of the first heat dissipation component 110 through the connecting pipelines 145, and the cooling component 160 is communicated to the second inner pipeline 136 of the second heat dissipation component 130 through the connecting pipelines 145. The heat dissipation medium M flows between the pump 150, the cooling component 160, the pipeline component 140, the first inner pipeline 116, and the second inner pipeline 136.

In a heat dissipation cycle, the heat dissipation medium M is driven by the pump 150 to flow into the cooling component 160 for the heat exchange. After the heat exchange, the heat dissipation medium M with the low thermal energy flows into the second inner pipeline 136 of the second heat dissipation component 130, thereby maintaining the second heat dissipation component 130 at the low temperature. The heat dissipation medium M with the low thermal energy then flows through the communicating pipeline 141 into the first inner pipeline 116 of the first heat dissipation component 110, and exchanges the heat with the heat source 200. After the heat exchange, the heat dissipation medium M with the high thermal energy flows away from the first heat dissipation component 110 and enters the pump 150. At this point, the heat dissipation power generation module 100 completes one heat dissipation cycle.

As shown in FIG. 2 and FIG. 3, the first heat dissipation component 110 and the second heat dissipation component 130 possess similar structures. The first heat dissipation component 110 includes an outer housing 117, with the first inner pipeline 116 located inside the outer housing 117. The second heat dissipation component 130 includes an outer housing 137, with the second inner pipeline 136 located inside the outer housing 137. Each of the first inner pipeline 116 and the second inner pipeline 136 include a flow region B1 and two heat dissipation regions B2. The flow region B1 is located between the two heat dissipation regions B2, and the flow region B1 is used for the flow of the heat dissipation medium M. The heat dissipation region B2 includes a fin structure to increase a surface area of the heat dissipation region B2, thereby improving the heat exchange efficiency between the heat dissipation region B2 and the outer housings 117, 137, to improve the heat dissipation efficiency of the heat dissipation power generation module 100.

In this embodiment, the number of heat sources 200 may be two, but not limited thereto. The heat source 200 may be a central processing unit, a graphics processing unit, or electronic elements around the processor, etc. The heat source 200 with the lower heat generation power may be disposed at a position adjacent to the communicating pipeline 141 (i.e., adjacent to a water inlet 1161 of the first inner pipeline 116), and the heat source 200 with the higher heat generation power may be disposed at a position away from the communicating pipeline 141 (i.e., away from the water inlet 1161 and adjacent to a water outlet 1162 of the first inner pipeline 116), but not limited thereto. When the heat dissipation medium M with the low thermal energy enters the first heat dissipation component 110, the heat dissipation medium M first exchanges the heat with the heat source 200 with the lower heat generation power, causing a slight increase in the thermal energy of the heat dissipation medium M, and then exchanges the heat with the heat source 200 with the higher heat generation power.

Thereby, the two heat sources 200 have their temperatures reduced to the target temperatures through the heat dissipation power generation module 100. During the process where the heat dissipation medium M exchanges the heat with the two heat sources 200 in sequence, the temperature of the heat dissipation medium M gradually increases, causing the temperature of the side S1 of the thermoelectric component 120 to gradually rise. That is, the temperature of the side S1 of the thermoelectric component 120 at a position adjacent to the water inlet 1161 is lower than the temperature of the side S1 at a position away from the water inlet 1161. Since the second heat dissipation component 130 maintains the uniform temperature overall, the amount of electrical energy generated by the thermoelectric component 120 may vary according to the position of the thermoelectric component 120.

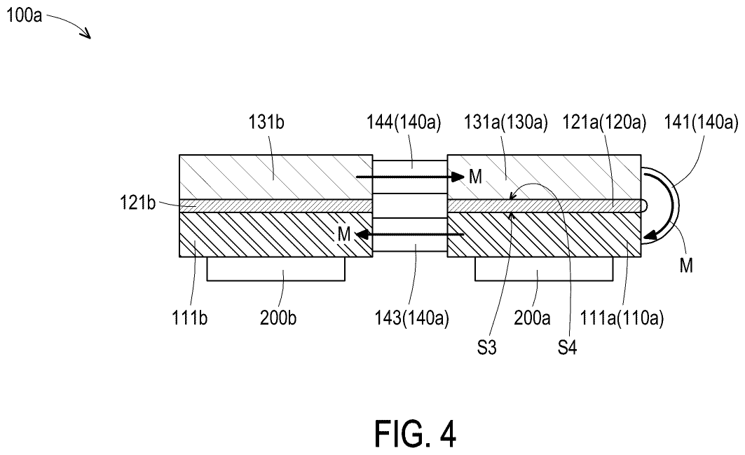

FIG. 4 is a cross-sectional view of a heat dissipation power generation module according to another embodiment of the disclosure, the structure of the elements are simplified here. Please refer to FIG. 2 and FIG. 4 at the same time, the heat dissipation power generation module 100a of this embodiment is similar to the previous embodiment. The difference between the two is that the first heat dissipation component 110a of this embodiment includes at least two first heat dissipation members 111a, 111b, the second heat dissipation component 130a includes at least two second heat dissipation members 131a, 131b, the thermoelectric component 120a includes at least two first thermoelectric members 121a, 121b, and at least one heat source includes at least two heat sources 200a, 200b. The pipeline component 140a includes at least one first pipeline 143, at least one second pipeline 144, and one communicating pipeline 141. Specifically, the number of first heat dissipation members, second heat dissipation members, first thermoelectric members, and heat sources is two each. The number of first pipelines, second pipelines, and communicating pipelines is one each.

The two first heat dissipation members 111a, 111b are thermally coupled with the corresponding two heat sources 200a, 200b respectively. The two opposite sides S3, S4 of the first thermoelectric member 121a are attached to the first heat dissipation member 111a and the second heat dissipation member 131a. The two opposite sides of the first thermoelectric member 121b are attached to the first heat dissipation member 111b and the second heat dissipation member 131b. The two adjacent first heat dissipation members 111a, 111b are connected by the first pipeline 143, and the two adjacent second heat dissipation members 131a, 131b are connected by the second pipeline 144. The two first heat dissipation members 111a, 111b may be viewed as connected in series, where the temperature of the first heat dissipation member 111b may be affected by the first heat dissipation member 111a (the heat source 200a). The communicating pipeline 141 is connected between the first heat dissipation member 111a and the second heat dissipation member 131a. The heat dissipation medium M flows between the pipeline component 140, the two first heat dissipation members 111a, 111b, and the two second heat dissipation members 131a, 131b. Through the first pipeline 143 and the second pipeline 144 of the pipeline component 140a, the distance between the two heat sources 200a, 200b may be relatively far apart, thereby improves the usability of the heat dissipation power generation module 100a. The heat dissipation power generation module 100a of this embodiment has the same effect as the previous embodiment, and is not repeated herein.

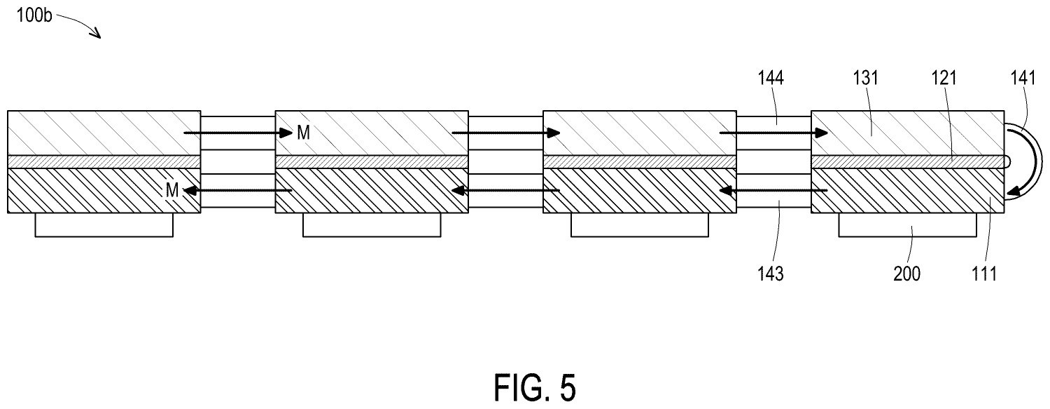

FIG. 5 is a cross-sectional view of a heat dissipation power generation module according to another embodiment of the disclosure. Please refer to FIG. 4 and FIG. 5 at the same time, the heat dissipation power generation module 100b of this embodiment is similar to the previous embodiment. The difference between the two is that the number of heat dissipation members and thermoelectric members connected in series is more than two, and their series connection relationship is formulated. For example, the number of first heat dissipation members 111, second heat dissipation members 131, and first thermoelectric members 121 is four each, while the number of first pipelines 143 and second pipelines 144 is correspondingly three each, and the number of communicating pipelines 141 is one, but not limited thereto. It could be known that the number of first heat dissipation members 111, second heat dissipation members 131, and first thermoelectric members 121 may be K, and the number of first pipelines 143 and second pipelines 144 may be (K−1), where K is a positive integer greater than 1. The heat dissipation power generation module 100b of this embodiment has the same effect as the previous embodiment, and is not repeated herein.

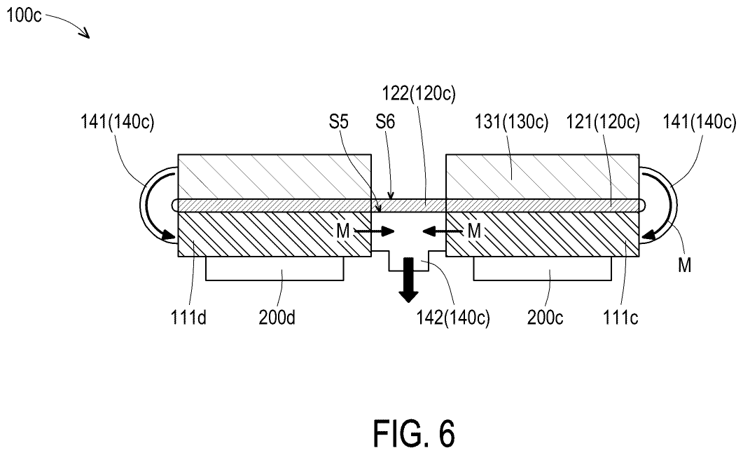

FIG. 6 is a cross-sectional view of a heat dissipation power generation module according to another embodiment of the disclosure. Please refer to FIG. 4 and FIG. 6 at the same time, the heat dissipation power generation module 100c of this embodiment is similar to the previous embodiment. The difference between the two is that the pipeline component 140c of this embodiment includes at least two communicating pipelines 141 and at least one converging pipeline 142. The number of communicating pipelines 141 is two, and the number of converging pipelines 142 is one, but not limited thereto. Two first heat dissipation members 111c, 111d are connected to the corresponding two second heat dissipation members 131 by the two communicating pipelines 141 respectively, and the two adjacent first heat dissipation members 111c, 111d are connected by the converging pipeline 142. The shape of the converging pipeline 142 is T-shaped, but not limited thereto. The converging pipeline 142 is communicated to the pump 150 (shown in FIG. 1).

The heat dissipation medium M with the high thermal energy after exchanges the heat with the heat sources 200c, 200d flows from the first heat dissipation members 111c, 111d to the converging pipeline 142, and then flows into the pump 150 (shown in FIG. 1) from the converging pipeline 142. Compared to the two first heat dissipation members 111a, 111b connected in series in FIG. 4, the two first heat dissipation members 111c, 111d of this embodiment may be viewed as connected in parallel. The two first heat dissipation members 111c, 111d are isolated from each other, the temperature of the first heat dissipation member 111c is not affected by the first heat dissipation member 111d (the heat source 200d), and the temperature of the first heat dissipation member 111d is not affected by the first heat dissipation member 111c (the heat source 200c). Thereby, the two first heat dissipation members 111c, 111d may exchanges the heat with two heat sources 200c, 200d with the higher heat generation power respectively, and may be used in the server with the plurality of heat sources 200c, 200d with the higher heat generation power.

The thermoelectric component 120c of this embodiment optionally includes at least one second thermoelectric member 122. The number of second thermoelectric members 122 corresponds to the number of converging pipelines 142 and is one. The second thermoelectric member 122 includes two opposite sides S5, S6, and the side S5 of the second thermoelectric member 122 is thermally coupled to the converging pipeline 142. Since the temperature of the external environment is lower than the temperature of the converging pipeline 142, a temperature difference is formed between the two sides S5, S6 of the second thermoelectric member 122, thereby the second thermoelectric member 122 generates the electrical energy. The heat dissipation power generation module 100c of this embodiment has the same effect as the previous embodiment, and is not repeated herein.

In addition, in an embodiment not shown, the second heat dissipation component 130c may include an auxiliary heat dissipation member such as a cooling fan or a heat sink. The second thermoelectric member 122 is disposed between the auxiliary heat dissipation member and the converging pipeline 142, and the heat dissipation medium M with the low thermal energy flows within the auxiliary heat dissipation member. The second thermoelectric member 122 may from the larger temperature difference through the auxiliary heat dissipation member and the converging pipeline 142, thereby generating the greater electrical energy.

Moreover, in the embodiments shown in FIG. 4 to FIG. 7, the heat dissipation power generation module may optionally include at least one water cooling head (not shown in the figures), the number of water cooling heads corresponds to the number of heat sources. The heat source is located between the first heat dissipation component and the water cooling head, to improve the heat dissipation efficiency of the heat dissipation power generation module.

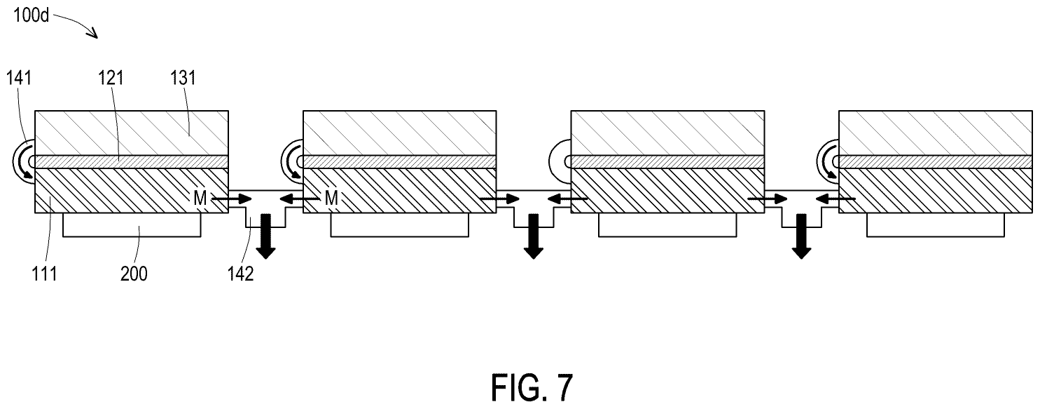

FIG. 7 is a cross-sectional view of a heat dissipation power generation module according to another embodiment of the disclosure. Please refer to FIG. 6 and FIG. 7 at the same time, the heat dissipation power generation module 100d of this embodiment is similar to the previous embodiment. The difference between the two is that the number of parallel connections of heat dissipation members and thermoelectric members of this embodiment is not limited to two, and their parallel relationship is formulated. For example, the number of first heat dissipation members 111, second heat dissipation members 131, and first thermoelectric members 121 is four each, the number of converging pipelines 142 is three, and the number of communicating pipelines 141 is four. The corresponding first heat dissipation members 111 and the second heat dissipation members 131 are connected by the communicating pipelines 141, and the two adjacent first heat dissipation members 111 are connected by the converging pipeline 142.

It could be known that, the number of first heat dissipation members 111, second heat dissipation members 131, first thermoelectric members 121, and communicating pipelines 141 may be N, and the number of converging pipelines 142 may be (N−1), where N is a positive integer greater than 1. The heat dissipation power generation module 100d of this embodiment has the same effect as the previous embodiment, and is not repeated herein.

In addition, in an embodiment not shown, the thermoelectric component 120d may include second thermoelectric members, the number of second thermoelectric members 122 may correspond to the number of converging pipelines 142 and may be three.

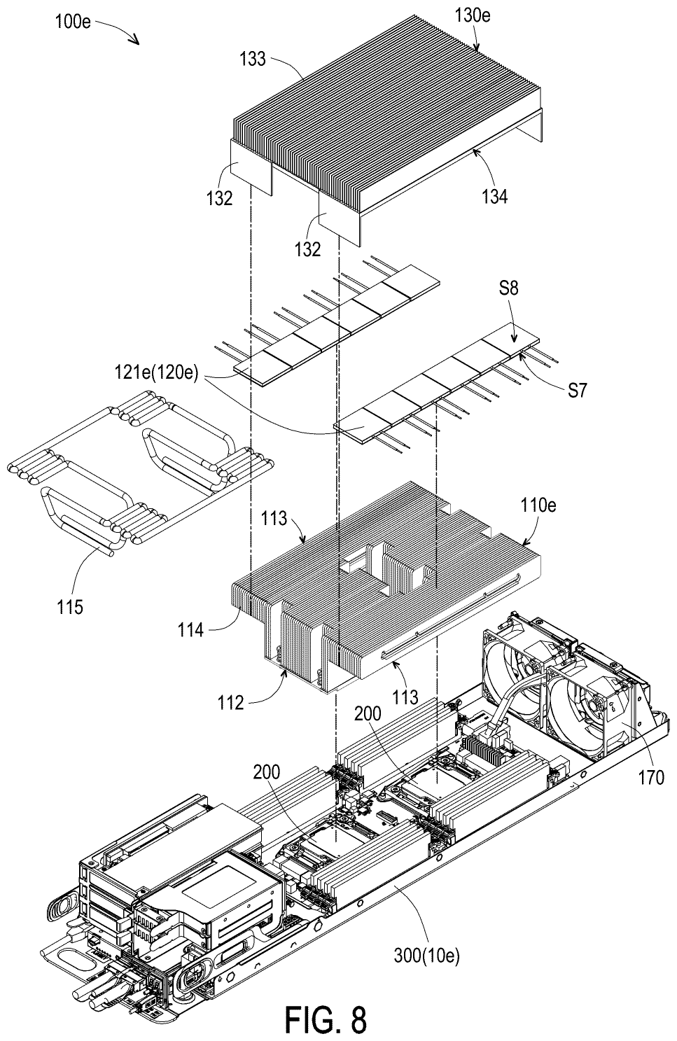

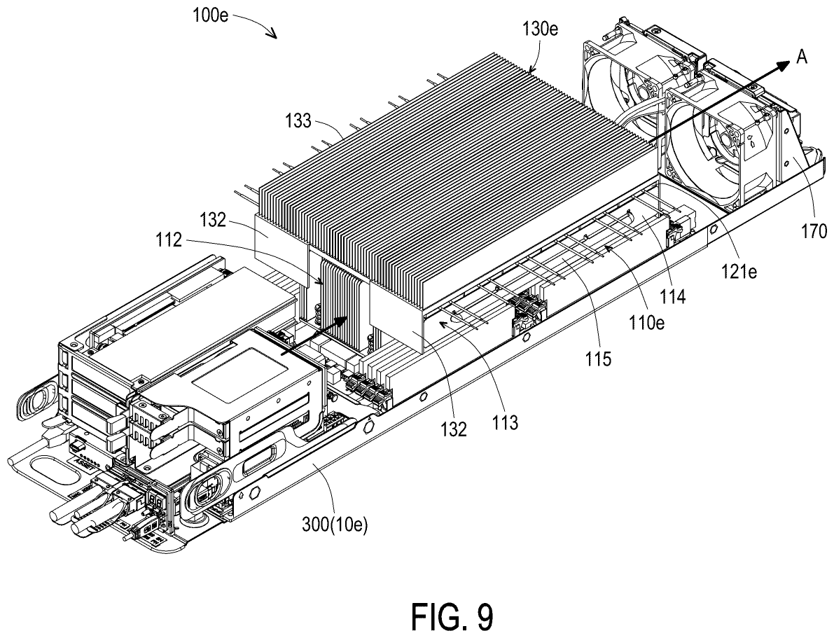

FIG. 8 is a cross-sectional view of a heat dissipation power generation module according to another embodiment of the disclosure. FIG. 9 is an exploded view of the heat dissipation power generation module in FIG. 8. Please refer to FIG. 8 and FIG. 9 at the same time. The heat dissipation power generation module 100e of this embodiment is an air-cooling heat dissipation power generation module. The heat dissipation power generation module 100e includes the first heat dissipation component 110e, the thermoelectric component 120e, and the second heat dissipation component 130e. The first heat dissipation component 110e includes a connecting portion 112 and two extension portions 113 connected to each other. The connecting portion 112 is connected to the heat source 200, and the two extension portions 113 are located at two opposite edges of the connecting portion 112 and away from the heat source 200. The thermal energy from the heat source 200 is guided from the connecting portion 112 to the extension portions 113. The first heat dissipation component 110e is T-shaped, but not limited thereto. The thermoelectric component 120e includes two first thermoelectric members 121e. The two first thermoelectric members 121e are disposed on the two extension portions 113 respectively. The first thermoelectric members 121e are located between the extension portions 113 and the second heat dissipation component 130e.

The first heat dissipation component 110e of this embodiment includes a first heat sink group 114 and a heat pipe 115. The heat pipe 115 is embedded within the first heat sink group 114, used to accelerate the transfer of the thermal energy dissipated from the heat sources 200 to the two extension portions 113. The second heat dissipation component 130e includes a second heat sink group 133 and a casing 134. The second heat sink group 133 is disposed at the casing 134. A part of the first heat sink group 114 and the heat pipe 115 form the connecting portion 112, the other part of the first heat sink group 114 and the heat pipe 115 form the two extension portions 113. The casing 134 of the second heat dissipation component 130e includes two baffles 132. The two heat sources 200 are contacted to the connecting portion 112.

The thermal energy dissipated from the heat source 200 is transferred from the connecting portion 112 to the second heat sink group 133, and is dissipated to the external environment through the second heat sink group 133 to dissipate the heat. The thermal energy from the heat source 200 is also transferred from the connecting portion 112 to the extension portions 113. The extension portions 113 with the high thermal energy form the high temperature on the side S7 of the first thermoelectric members 121e, and the second heat sink group 133 with the low thermal energy forms the low temperature on the side S8 of the first thermoelectric members 121e. The first thermoelectric members 121e generate the electrical energy through the temperature difference between the two sides S7 and S8.

The heat dissipation power generation module 100e further includes at least one fan component 170, used to form an airflow A. The fan component 170 is disposed on the circuit board 300 of the server 10e. The two baffles 132 of the second heat dissipation component 130e are located between the two extension portions 113 and the fan component 170, and are located in a path of the airflow A to block the airflow A. The airflow A exchanges the heat with the heat sources 200 through the connecting portion 112 of the first heat dissipation component 110e, to improve the heat dissipation efficiency of the heat dissipation power generation module 100e. Since the airflow A is blocked by the baffles 132, the extension portions 113 of the first heat dissipation component 110e still have the higher thermal energy, and may still generate the high temperature on the side S7 of the first thermoelectric members 121e. The airflow A may also exchange the heat with the second heat dissipation component 130e, to further lower the temperature of the second heat dissipation component 130e, generating the even lower temperature on the side S8 of the first thermoelectric members 121. Thereby, the heat dissipation power generation module 100e may generate electrical energy through the first thermoelectric members 121e without affecting the heat dissipation of the heat source 200.

The number of fan components 170 of this embodiment is one, and the fan component 170 includes two fans, but not limited thereto. In an embodiment not shown, the number of fan components 170 may be two. The first heat dissipation component 110e, the second heat dissipation component 130e, and the thermoelectric component 120e are located between the two fan components 170. The two fan components 170 are located in the path of the airflow A. One fan component is used to generate the airflow A, and the other fan component is used to improve the velocity of the airflow A, thereby causing the airflow A to exit the heat dissipation power generation module 100e (the server 10e) more rapidly, to improve the heat dissipation efficiency of the heat dissipation power generation module 100e.

In summary, the first heat dissipation component of the heat dissipation power generation module of the disclosure exchanges heat with the heat source of the server, forming a high temperature on one side of the thermoelectric component. The second heat dissipation component forms a low temperature on the other side of the thermoelectric component. The thermoelectric component generates the electrical energy through the temperature difference at the two sides. Thereby, the heat dissipation power generation module may dissipate heat from the heat source while simultaneously recycling the thermal energy dissipated by the heat source to generate the electrical energy, achieving the efficacy of energy recycling and heat dissipation.

What is claimed is:

1. A heat dissipation power generation module, adapted for a server, the heat dissipation power generation module comprising:
a first heat dissipation component, thermally coupled to at least one heat source of the server;
a thermoelectric component, disposed on the first heat dissipation component; and
a second heat dissipation component, the thermoelectric component is located between the first heat dissipation component and the second heat dissipation component,
the first heat dissipation component and the second heat dissipation component form a temperature difference at two opposite sides of the thermoelectric component, and the thermoelectric component generates an electrical energy through the temperature difference.

2. The heat dissipation power generation module according to claim 1, further comprising a pipeline component, wherein the first heat dissipation component comprises a first inner pipeline, the second heat dissipation component comprises a second inner pipeline, the pipeline component connects the first inner pipeline and the second inner pipeline, a heat dissipation medium flows within the pipeline component, the first inner pipeline and the second inner pipeline.

3. The heat dissipation power generation module according to claim 2, further comprising a pump and a cooling component, the pump is communicated with the cooling component and the first inner pipeline, the cooling component is communicated with the second inner pipeline, a heat dissipation medium flows between the pump, the cooling component, the first inner pipeline and the second inner pipeline.

4. The heat dissipation power generation module according to claim 2, wherein the first heat dissipation component comprises at least two first heat dissipation members, the second heat dissipation component comprises at least two second heat dissipation members, the thermoelectric component comprises at least two first thermoelectric members, the at least one heat source comprises at least two heat sources, each of the at least two first thermoelectric members has two opposite sides attached to each of the at least two first heat dissipation members and each of the at least two second heat dissipation members, and each of the at least two first heat dissipation members is thermally coupled to the at least two heat sources.

5. The heat dissipation power generation module according to claim 4, further comprising a pipeline component, the pipeline component comprising at least one first pipeline, at least one second pipeline and a communicating pipeline, the adjacent at least two first heat dissipation members are communicated by each of the at least one first pipeline, the adjacent at least two second heat dissipation members are communicated by each of the at least one second pipeline, the communicating pipeline connects between one of the at least two first heat dissipation members and one of the at least two second heat dissipation members, a heat dissipation medium flows between the pipeline component, the at least two first heat dissipation members and the at least two second heat dissipation members.

6. The heat dissipation power generation module according to claim 4, further comprising a pipeline component, the pipeline component comprising at least two communicating pipelines and at least one converging pipeline, each of the at least two first heat dissipation members and each of the at least two second heat dissipation members are connected by each of the at least two communicating pipelines, the adjacent at least two first heat dissipation members are connected by each of the at least one converging pipeline.

7. The heat dissipation power generation module according to claim 6, the thermoelectric component further comprising at least one second thermoelectric member, each of the at least one second thermoelectric member comprises two opposite sides, one of the two sides of each of the at least one second thermoelectric member is thermally coupled to each of the at least one converging pipeline, the at least one second thermoelectric member generates the electrical energy through the temperature difference between the two sides.

8. The heat dissipation power generation module according to claim 1, wherein the first heat dissipation component comprises a connecting portion and two extension portions connected to each other, the connecting portion is connected to the at least one heat source, the two extension portions are located on opposite edges of the connecting portion, the thermoelectric component comprises two first thermoelectric members, the two first thermoelectric members are respectively disposed on the two extension portions.

9. The heat dissipation power generation module according to claim 8, further comprising at least one fan component, wherein the second heat dissipation component comprises two baffles, the two baffles are located between the two extension portions and the at least one fan component, the two baffles are located in a movement path of an airflow formed by the at least one fan component, to block the airflow.

10. The heat dissipation power generation module according to claim 9, wherein the first heat dissipation component comprises a first heat sink group and a heat pipe, the second heat dissipation component comprises a second heat sink group and a casing, the heat pipe is embedded in the first heat sink group, the casing comprises the two baffles, the second heat sink group is disposed on the casing.
